(19) United States
(12) Patent Application Publication
(10) Pub. No.: US 2024/0213085 A1
(43) Pub. Date: Jun. 27, 2024

(54) LARGE-AREA III-V SEMICONDUCTOR LAYER TRANSFERRING METHOD

(71) Applicant: ELECTRONICS AND TELECOMMUNICATIONS RESEARCH INSTITUTE, Daejeon (KR)

(72) Inventors: Ho Sung KIM, Daejeon (KR); Daemyeong GEUM, Daejeon (KR)

(73) Assignee: ELECTRONICS AND TELECOMMUNICATIONS RESEARCH INSTITUTE, Daejeon (KR)

(21) Appl. No.: 18/488,718

(22) Filed: Oct. 17, 2023

(30) Foreign Application Priority Data
Dec. 23, 2022 (KR) 10-2022-0183580

(51) Int. Cl. H01L 21/762; H01L 21/02

(52) U.S. Cl. CPC H01L 21/76251; H01L 21/02543; H01L 21/02546; H01L 21/02587; H01L 21/02664

(57) ABSTRACT

Disclosed is a large-area III-V semiconductor layer transferring method. The large-area III-V semiconductor layer transferring method includes: forming III-V semiconductor dies on a lower substrate; forming dielectric patterns on the III-V semiconductor dies and the lower substrate exposed between the III-V semiconductor dies; forming a lower III-V semiconductor layer on the dielectric patterns and the III-V semiconductor dies; forming a sacrificial layer on the lower III-V semiconductor layer; forming an upper III-V semiconductor layer on the sacrificial layer; bonding an upper substrate onto the III-V semiconductor layer; and removing the sacrificial layer.

### CROSS-REFERENCE TO RELATED APPLICATIONS

This U.S. non-provisional patent application claims priority under 35 U.S.C. § 119 of Korean Patent Application No. 10-2022-0183580, filed on Dec. 23, 2022, the entire contents of which are hereby incorporated by reference.

### BACKGROUND

The present disclosure relates to a III-V semiconductor layer transferring method, and more particularly, to a large-area III-V semiconductor layer transferring method.

In recent years, since a demand for energy efficiency improvement, big data transmission, and high-speed data processing increases as new industries such as artificial intelligence, 5G, electric vehicles, autonomous driving, and smartphones are rapidly developed, a silicon semiconductor has reached a material limit that may not be overcome with the silicon semiconductor alone. As a result, an attempt of fusing a heterogeneous semiconductor to overcome the limit of the silicon material is rapidly developing. In particular, researches on hetero-junction with a III-V compound semiconductor are developing rapidly in the field of a light source that may not be realized with the silicon semiconductor. A method for integrating a silicon semiconductor device and a compound semiconductor device includes: 1) direct growth epitaxy which directly grows a III-V compound semiconductor on a silicon substrate; and 2) regrowth epitaxy which performs chip bonding of bonding a compound semiconductor device at a specific position on a silicon substrate, implants a III-V compound semiconductor buffer layer on the silicon substrate, and then regrows the device.

### SUMMARY

The present disclosure provides a large-area III-V semiconductor layer transferring method capable of minimizing a defect.

An embodiment of the inventive concept provides a large-area III-V semiconductor layer transferring method including: forming III-V semiconductor dies on a lower substrate; forming dielectric patterns on the III-V semiconductor dies and the lower substrate exposed between the III-V semiconductor dies; forming a lower III-V semiconductor layer on the dielectric patterns and the III-V semiconductor dies; forming a sacrificial layer on the lower III-V semiconductor layer; forming an upper III-V semiconductor layer on the sacrificial layer; bonding an upper substrate onto the III-V semiconductor layer; and removing the sacrificial layer.

In an embodiment, each of the III-V semiconductor dies may include InP and GaAs.

In an embodiment, each of the dielectric patterns may include silicon oxide or aluminum oxide formed by an epitaxial lateral over growth (ELOG) method.

In an embodiment, each of the dielectric patterns may have a T-shape.

In an embodiment, each of the III-V semiconductor dies may have a comb shape.

In an embodiment, the lower substrate may include a silicon wafer.

In an embodiment, the upper substrate may include a silicon on insulator (SOI) substrate.

In an embodiment, each of the dielectric patterns may have a thickness of about 1 μm or less.

In an embodiment, the lower III-V semiconductor layer may include InP or GaAs transferred by a wafer bonding method.

In an embodiment, the upper III-V semiconductor layer may include InP or GaAs formed by the epitaxial lateral over growth (ELOG) method.

In an embodiment of the inventive concept, a large-area III-V semiconductor layer transferring method includes: forming a III-V/Si template on a lower substrate; forming a sacrificial layer on the III-V/Si template; forming an upper III-V semiconductor layer on the sacrificial layer; bonding an upper substrate onto the III-V semiconductor layer; and removing the sacrificial layer.

In an embodiment, the forming of the III-V/Si template may further include: transferring III-V semiconductor dies; forming dielectric patterns on the III-V semiconductor dies and the lower substrate exposed between the III-V semiconductor dies; and forming a lower III-V semiconductor layer on the dielectric patterns and the III-V semiconductor dies.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a flowchart representing a III-V semiconductor layer transferring method according to an embodiment of the inventive concept; and

FIGS. 2 to 8 are process cross-sectional views illustrating the III-V semiconductor layer transferring method according to an embodiment of the inventive concept.

### DETAILED DESCRIPTION

Hereinafter, exemplary embodiments of the present invention will be described in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

In the specification, the technical terms are used only for explaining a specific exemplary embodiment while not limiting the present invention. In the specification, the terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components. Also, in the specification, chips, pads, wiring, and adhesive layers may be understood as those generally used in the semiconductor field. The reference numerals presented according to the order of descriptions of the preferred embodiments are not necessarily limited to that order.

The above-described features are detailed embodiments for implementing the present invention. The present invention will include not only the embodiments described above, but also embodiments that may be simply modified in design or easily changed. Also, the present invention will also include technologies that may be easily modified and implemented in the future by using the embodiments described above.

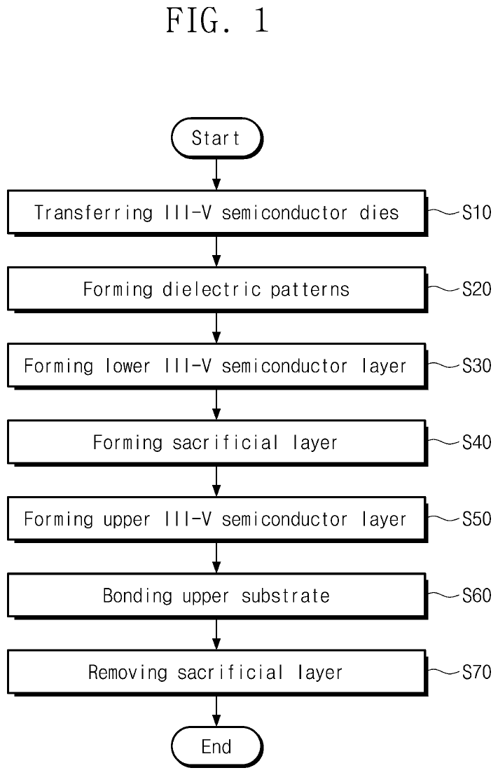

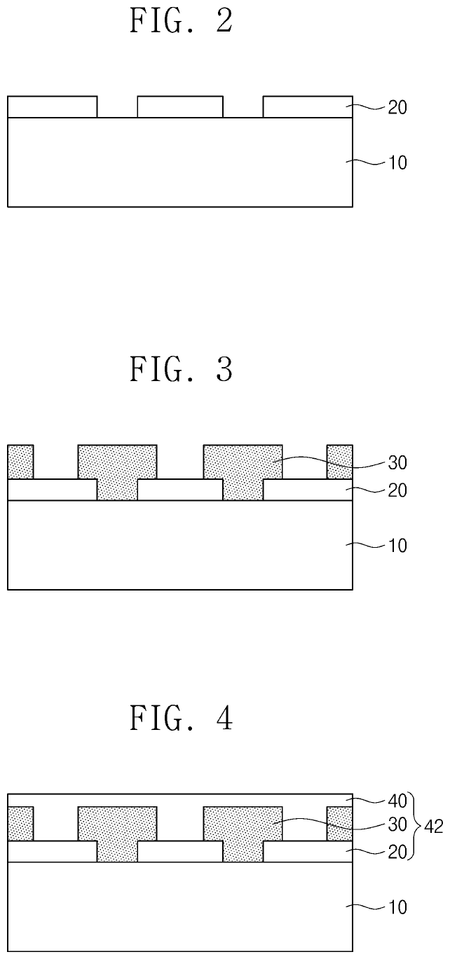

FIG. 1 is a flowchart representing an example of a III-V semiconductor layer transferring method according to an embodiment of the inventive concept. FIGS. 2 to 8 are process cross-sectional views illustrating the III-V semiconductor layer transferring method according to an embodiment of the inventive concept.

Referring to FIGS. 1 and 2, III-V semiconductor dies 20 are transferred onto a lower substrate 10 in operation S10. The lower substrate 10 may include a silicon wafer. The transferred III-V semiconductor dies 20 may include defect-free III-V semiconductor crystals of InP crystals or GaAs crystals. The III-V semiconductor dies 20 may be formed by a wafer bonding process and a substrate removal process of InP or GaAs. The III-V semiconductor dies 20 adjacent to each other may have a distance of about 3 μm or less to expose a portion of a top surface of the lower substrate 10. The distance may be a transfer margin or a bonding margin of the III-V semiconductor dies 20. However, the embodiment of the inventive concept is not limited thereto.

Referring to FIGS. 1 and 3, dielectric patterns 30 are formed on the III-V semiconductor dies 20 and the lower substrate 10 exposed between the III-V semiconductor dies 20 in operation S20. The dielectric patterns 30 that are formed for an epitaxial lateral over growth (ELOG) process may include silicon oxide (SiO₂) or aluminum oxide (Al₂O₃). The dielectric patterns 30 may be heat-treated at a high temperature of about 600° C. or more through an ELOG method. Each of the dielectric patterns 30 may have a T-shape from a vertical perspective. Each of the dielectric patterns 30 may have a thickness of about 1 μm or less. Since each of the III-V semiconductor dies 20 does not have a defect, the high-quality III-V semiconductors may be grown by using only the dielectric patterns 30 each having a thickness of about 1 μm.

Referring to FIGS. 1 and 4, a lower III-V semiconductor layer 40 is formed on the transferred III-V semiconductor 20 and the dielectric patterns 30 in operation S30. For example, the lower III-V semiconductor layer 40 may include InP and GaAs formed by the ELOG method. According to an embodiment, the lower III-V semiconductor layer 40 may have a comb shape from the vertical perspective. The lower substrate 10, the transferred III-V semiconductor 20, the dielectric patterns 30, and the lower III-V semiconductor layer 40 may be used as a III-V/Si template 42 for forming an upper III-V semiconductor layer 60 that will be formed later.

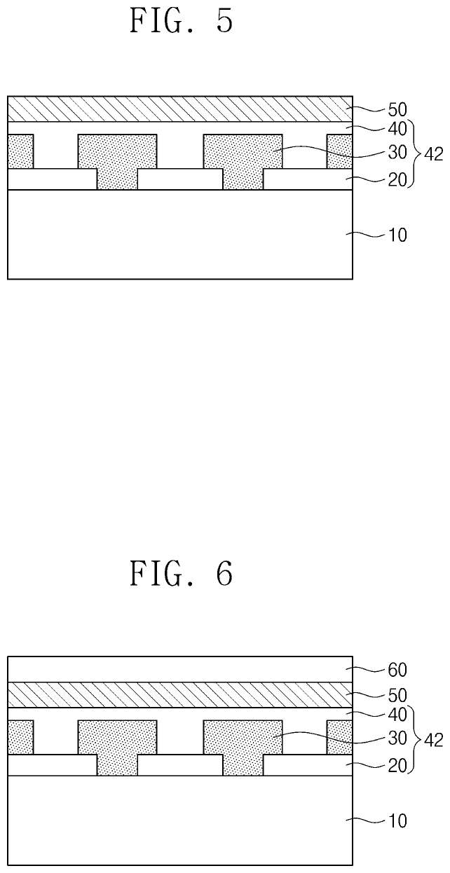

Referring to FIGS. 1 and 5, a sacrificial layer 50 is formed on the lower III-V semiconductor layer 40 in operation S40. The sacrificial layer 50 may have etch selectivity with the lower III-V semiconductor layer 40. For example, the sacrificial layer 50 may include an Al compound semiconductor (AlAs or InAlAs). The AlAs may be selectively etched with the GaAs layer, and the InAlAs may be selectively etched with the InP layer. However, the embodiment of the inventive concept is not limited thereto.

Referring to FIGS. 1 and 6, the upper III-V semiconductor layer 60 is formed on the sacrificial layer 50 in operation S50. The upper III-V semiconductor layer 60 may include an InP or GaAs-based compound semiconductor.

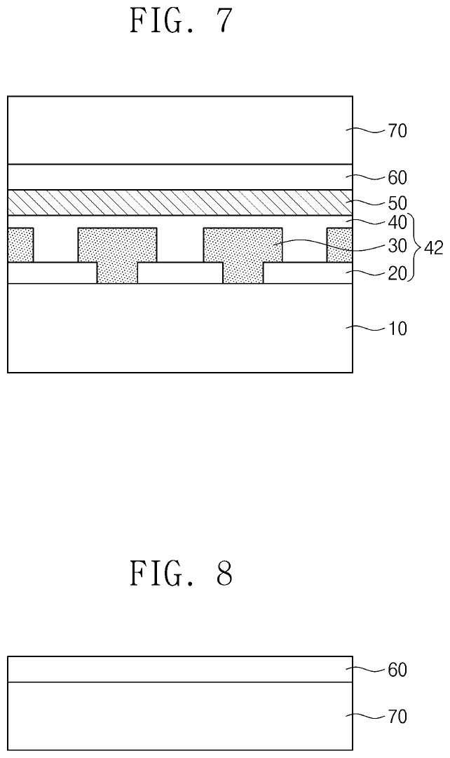

Referring to FIGS. 1 and 7, the upper substrate 70 is bonded onto the upper III-V semiconductor layer 60. in operation S60. The upper substrate 70 may include a silicon on insulator (SOI) substrate. The bonding process of the upper substrate 70 includes a pressing process and a heat treatment process. The upper substrate 70 may be a target substrate.

Referring to FIGS. 1 and 8, the sacrificial layer 50 is removed in operation S70. The sacrificial layer 50 may be removed by a wet etching method of using a buffer solution (HF) as an etchant. The lower substrate 10, the transferred III-V semiconductor 20, the dielectric patterns 30, and a III-V/Si template 42 of the lower III-V semiconductor layer 40 may be separated from the upper III-V semiconductor layer 60. The upper III-V semiconductor layer 60 may be transferred to the upper substrate 70. A top surface of the upper III-V semiconductor layer 60 may be exposed. The upper III-V semiconductor layer 60 may have a large area. The III-V/Si template 42 may be reused when the sacrificial layer 50 and the upper III-V semiconductor layer 60 are formed. That is, the III-V/Si template 42 may repeatedly generate a plurality of III-V semiconductor layers 60 by using the upper sacrificial layer 50.

Thus, the large-area III-V semiconductor layer transferring method according to an embodiment of the inventive concept may transfer a large-area high-quality upper III-V semiconductor layers 60 onto the upper substrate 70 by using the III-V/Si template 42 including the III-V semiconductor pattern 20 transferred onto the lower substrate and the lower III-V semiconductor layer 40 on the lower III-V semiconductor layer 40 disposed on the dielectric patterns 30.

As described above, the large-area III-V semiconductor layer transferring method according to the embodiment of the inventive concept may transfer the high-quality III-V layer onto the target substrate by using the III-V/Si template in the large area manner.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A large-area III-V semiconductor layer transferring method comprising:
forming III-V semiconductor dies on a lower substrate;
forming dielectric patterns on the III-V semiconductor dies and the lower substrate exposed between the III-V semiconductor dies;
forming a lower III-V semiconductor layer on the dielectric patterns and the III-V semiconductor dies;
forming a sacrificial layer on the lower III-V semiconductor layer;
forming an upper III-V semiconductor layer on the sacrificial layer;
bonding an upper substrate onto the III-V semiconductor layer; and
removing the sacrificial layer.

2. The large-area III-V semiconductor layer transferring method of claim 1, wherein each of the III-V semiconductor dies comprises InP and GaAs.

3. The large-area III-V semiconductor layer transferring method of claim 1, wherein each of the dielectric patterns comprises silicon oxide formed by an epitaxial lateral over growth (ELOG) method.

4. The large-area III-V semiconductor layer transferring method of claim 1, wherein each of the dielectric patterns has a T-shape.

5. The large-area III-V semiconductor layer transferring method of claim 1, wherein each of the III-V semiconductor dies has a comb shape.

6. The large-area III-V semiconductor layer transferring method of claim 1, wherein the lower substrate comprises a silicon wafer.

7. The large-area III-V semiconductor layer transferring method of claim 1, wherein the upper substrate comprises a silicon on insulator (SOI) substrate.

8. The large-area III-V semiconductor layer transferring method of claim 1, wherein each of the dielectric patterns has a thickness of about 1 μm or less.

9. The large-area III-V semiconductor layer transferring method of claim 1, wherein the lower III-V semiconductor layer comprises InP or GaAs formed by an epitaxial lateral over growth (ELOG) method.

10. The large-area III-V semiconductor layer transferring method of claim 1, wherein the upper III-V semiconductor layer comprises InP or GaAs on a large-area lower III-V/Si substrate.

11. A large-area III-V semiconductor layer transferring method comprising:
forming a III-V/Si template on a lower substrate;
forming a sacrificial layer on the III-V/Si template;
forming an upper III-V semiconductor layer on the sacrificial layer;
bonding an upper substrate onto the III-V semiconductor layer; and
removing the sacrificial layer.

12. The large-area III-V semiconductor layer transferring method of claim 11, wherein the forming of the III-V/Si template further comprises:
transferring III-V semiconductor dies;
forming dielectric patterns on the III-V semiconductor dies and the lower substrate exposed between the III-V semiconductor dies; and
forming a lower III-V semiconductor layer on the dielectric patterns and the III-V semiconductor dies.
